(19) United States
(12) Patent Application Publication
(10) Pub. No.: US 2011/0244612 A1
(43) Pub. Date: Oct. 6, 2011

(54) OPTICAL DEVICE WAFER PROCESSING METHOD

(75) Inventor: Kazuma Sekiya, Ota-Ku (JP)

(73) Assignee: DISCO CORPORATION, Tokyo (JP)

(21) Appl. No.: 13/077,203

(22) Filed: Mar. 31, 2011

(30) Foreign Application Priority Data
Apr. 6, 2010 (JP) 2010-087826

(51) Int. Cl. H01L 21/78

(52) U.S. Cl. 438/33; 257/E21.599

(57) ABSTRACT

An optical device wafer processing method for dividing an optical device wafer into individual optical devices along a plurality of crossing streets formed on the front side of the wafer. The wafer is composed of a substrate and an optical device layer formed on the front side of the substrate. The individual optical devices are respectively formed in a plurality of regions partitioned by the streets. The optical device wafer processing method includes the steps of cutting the back side of the substrate along each street by using a cutting blade to thereby form a first cut groove as a first break start point on the back side of the substrate along each street, cutting the front side of the wafer along each street by using a cutting blade after forming the first cut groove to thereby form a second cut groove as a second break start point on the front side of the wafer along each street so that the second cut groove has a depth reaching the front side of the substrate, and applying an external force to the wafer after forming the second cut groove to thereby break the wafer along each street where the first and second cut grooves are formed, thereby dividing the wafer into the individual optical devices.

### BACKGROUND OF THE INVENTION

1. Field of the Invention

The present invention relates to an optical device wafer processing method for dividing an optical device wafer into individual optical devices along a plurality of crossing streets formed on the front side of the optical device wafer, the optical device wafer being composed of a substrate and an optical device layer formed on the front side of the substrate, the individual optical devices being respectively formed in a plurality of regions partitioned by the streets.

2. Description of the Related Art

In an optical device fabrication process, an optical device layer of a gallium nitride compound semiconductor is formed on the front side of a substantially disk-shaped substrate such as a sapphire substrate and a silicon carbide substrate, and this optical device layer is partitioned by a plurality of crossing streets into a plurality of regions where optical devices such as light emitting diodes (LEDs) and laser diodes (LDs) are respectively formed, thus constituting an optical device wafer. The optical device wafer is cut along the streets to thereby divide the regions where the optical devices are formed from each other, thus obtaining the individual optical devices.

Cutting of the optical device wafer along the streets is usually performed by using a cutting apparatus called a dicing saw. This cutting apparatus includes a chuck table for holding a workpiece, cutting means for cutting the workpiece held on the chuck table, and feeding means for relatively moving the chuck table and the cutting means. The cutting means includes a rotating spindle, a cutting blade mounted on the rotating spindle, and a driving mechanism for rotationally driving the rotating spindle. The cutting blade is composed of a disk-shaped base and an annular cutting edge mounted on a side surface of the base along the outer circumference thereof. The cutting edge is formed by fixing diamond abrasive grains having a grain size of about 3 μm to the base by electroforming so that the thickness of the cutting edge becomes about 20 μm, for example.

However, the substrate of the optical device wafer, such as a sapphire substrate and a silicon carbide substrate, has high Mohs hardness, so that cutting of the substrate by the cutting blade is not always easy. Accordingly, the depth of cut by the cutting blade cannot be set large, so that a cutting step must be performed plural times to cut the optical device wafer, causing a reduction in productivity.

As another method of dividing an optical device wafer along the streets, a laser processing method using a pulsed laser beam having an absorption wavelength to the optical device wafer has been proposed to solve the problem. In this laser processing method, the pulsed laser beam is applied to the optical device wafer along the streets to thereby form a laser processed groove on the optical device wafer along each street as a break start point. Thereafter, an external force is applied to the optical device wafer along each street where the laser processed groove is formed as the break start point, thereby breaking the optical device wafer along each street (see Japanese Patent Laid-open No. Hei 10-305420, for example).

### SUMMARY OF THE INVENTION

However, in the case that a laser beam having an absorption wavelength to a sapphire substrate constituting an optical device wafer is applied to the optical device wafer along the streets formed on the front side of the sapphire substrate to thereby form a laser processed groove along each street, there is a problem such that a modified substance produced in laser processing may be deposited to the side wall surface of each optical device such as a light emitting diode, causing a reduction in luminance of each optical device, so that the quality of each optical device is reduced.

It is therefore an object of the present invention to provide an optical device wafer processing method which can divide an optical device wafer into individual optical devices without reducing the quality of each optical device.

In accordance with an aspect of the present invention, there is provided an optical device wafer processing method for dividing an optical device wafer into individual optical devices along a plurality of crossing streets formed on the front side of the optical device wafer, the optical device wafer being composed of a substrate and an optical device layer formed on the front side of the substrate, the individual optical devices being respectively formed in a plurality of regions partitioned by the streets, the optical device wafer processing method including a first break start point forming step of cutting the back side of the substrate along each street by using a cutting blade mainly composed of diamond abrasive grains to thereby form a first cut groove as a first break start point on the back side of the substrate along each street; a second break start point forming step of cutting the front side of the optical device wafer along each street by using a cutting blade mainly composed of diamond abrasive grains after performing the first break start point forming step to thereby form a second cut groove as a second break start point on the front side of the optical device wafer along each street so that the second cut groove has a depth reaching the front side of the substrate; and a wafer dividing step of applying an external force to the optical device wafer after performing the second break start point forming step to thereby break the optical device wafer along each street where the first cut groove and the second cut groove are formed, thereby dividing the optical device wafer into the individual optical devices.

In the optical device wafer processing method according to the present invention, the first cut groove as the first break start point is formed along each street on the back side of the substrate of the optical device wafer by using a cutting blade, and the second cut groove as the second break start point is formed along each street on the front side of the optical device wafer by using a cutting blade so as to reach the front side of the substrate. Thereafter, the optical device wafer is broken along each street where the first and second cut grooves are formed as a break start point, thereby dividing the optical device wafer into the individual optical devices. Accordingly, cracks contributing to the division of the optical device wafer grow from the first and second cut grooves formed on the back side and the front side of the substrate, respectively, thereby attaining effective division of the optical device wafer. Further, a modified substance absorbing light to cause a reduction in luminance is not produced, so that the luminance of each optical device is not reduced.

Further, the first cut grooves as the first break start point and the second cut grooves as the second break start point are formed by a cutting blade mainly composed of diamond abrasive grains. Accordingly, the inner surfaces of the first and second cut grooves are formed as rough surfaces, so that light can be effectively emitted from each optical device, thereby improving the luminance.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of an optical device wafer to be processed by the optical device wafer processing method according to the present invention;

FIG. 1B is an enlarged sectional view of an essential part of the optical device wafer shown in FIG. 1A;

FIGS. 2A and 2B are perspective views for illustrating a protective member attaching step in the optical device wafer processing method according to the present invention;

FIG. 3 is a perspective view of an essential part of a cutting apparatus for performing a first break start point forming step in the optical device wafer processing method according to the present invention;

FIGS. 4A to 4C are sectional side views for illustrating the first break start point forming step in the optical device wafer processing method according to the present invention;

FIGS. 5A and 5B are perspective views for illustrating a wafer supporting step in the optical device wafer processing method according to the present invention;

FIG. 6 is a perspective view for illustrating a second break start point forming step in the optical device wafer processing method according to the present invention;

FIGS. 7A to 7C are sectional side views for illustrating the second break start point forming step in the optical device wafer processing method according to the present invention;

FIG. 8 is a perspective view of a wafer dividing apparatus for performing a wafer dividing step in the optical device wafer processing method according to the present invention; and

FIGS. 9A and 9B are sectional side views for illustrating the wafer dividing step in the optical device wafer processing method according to the present invention.

### DETAILED DESCRIPTION OF THE PREFERRED EMBODIMENTS

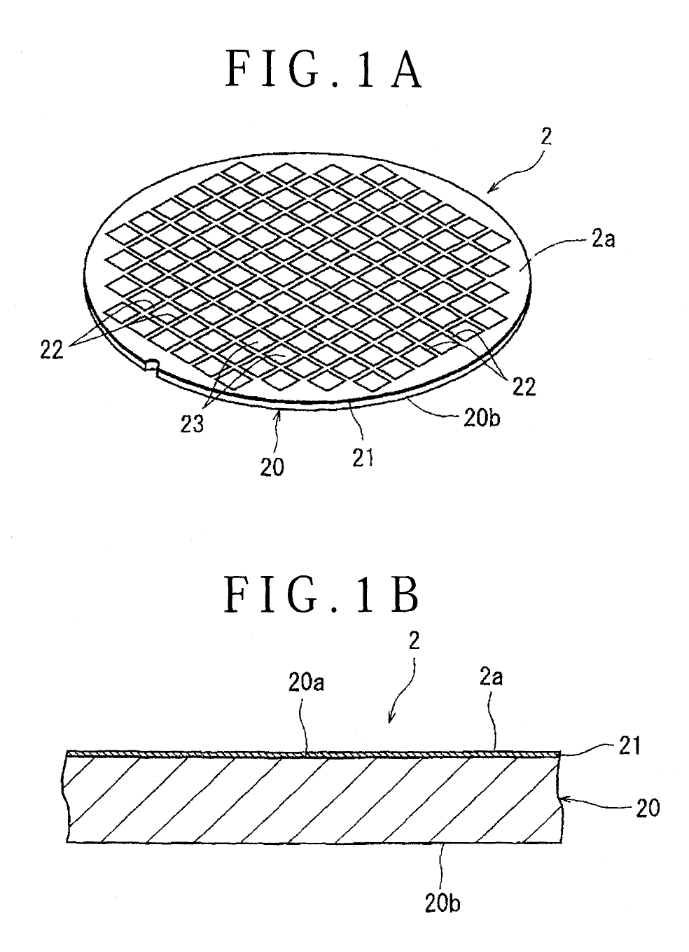

A preferred embodiment of the optical device wafer processing method according to the present invention will now be described in detail with reference to the attached drawings. FIG. 1A is a perspective view of an optical device wafer 2 to be processed by the optical device wafer processing method according to the present invention, and FIG. 1B is an enlarged sectional view of an essential part of the optical device wafer 2 shown in FIG. 1A. The optical device wafer 2 shown in FIGS. 1A and 1B is composed of a sapphire substrate 20 having a front side 20a and a back side 20b and a light emitting layer (epitaxial layer) 21 as an optical device layer formed on the front side 20a of the sapphire substrate 20. Reference numeral 2a denotes the front side of the optical device wafer 2. For example, the sapphire substrate 20 has a thickness of 100 μm, and the light emitting layer 21 has a thickness of 5 μm. The light emitting layer 21 is formed from a nitride semiconductor. The light emitting layer 21 is partitioned into a plurality of rectangular regions by a plurality of crossing streets 22. In these rectangular regions, a plurality of optical devices 23 such as light emitting diodes (LEDs) and laser diodes (LDs) are formed. There will now be described a processing method for dividing the optical device wafer 2 into the individual optical devices 23 along the streets 22.

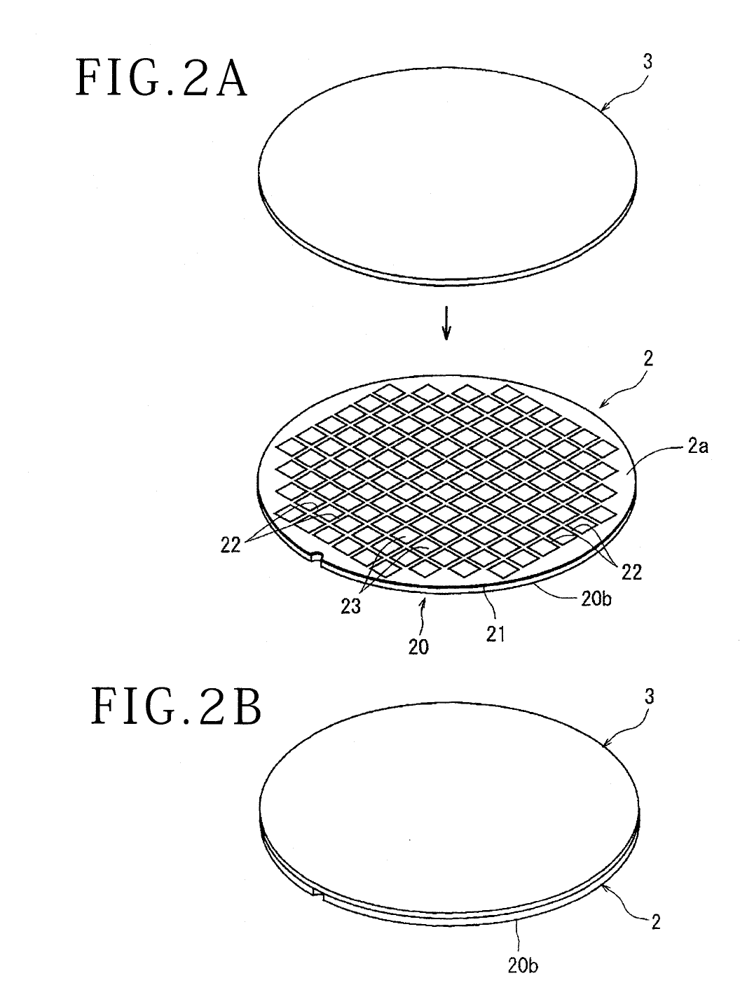

First, a protective member attaching step is performed in such a manner that a protective member is attached to the front side 2a of the optical device wafer 2 to protect the optical devices 23 formed on the front side 20a of the sapphire substrate 20 constituting the optical device wafer 2. More specifically, as shown in FIGS. 2A and 2B, a protective tape 3 as the protective member is attached to the front side 2a of the optical device wafer 2. The protective tape 3 is composed of a base sheet and an adhesive layer formed on the front side of the base sheet. For example, the base sheet is formed of polyvinyl chloride (PVC) and has a thickness of 100 μm. The adhesive layer is formed of acrylic resin and has a thickness of about 5 μm.

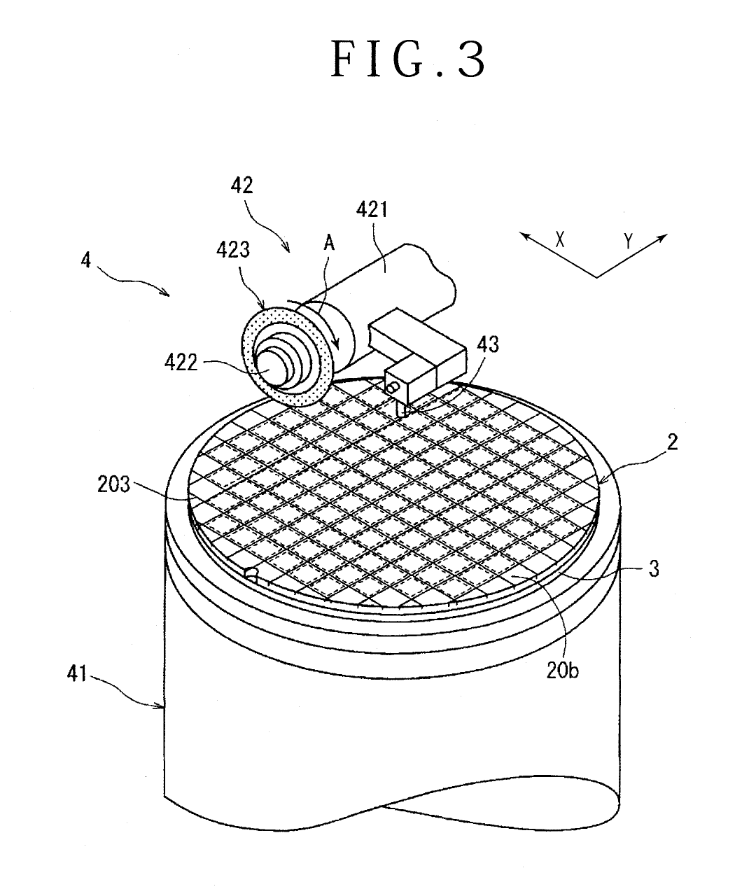

After performing the protective member attaching step to attach the protective tape 3 to the front side 2a of the optical device wafer 2, a first break start point forming step is performed in such a manner that the back side 20b of the substrate 20 is cut along each street 22 by using a cutting blade mainly composed of diamond abrasive grains to thereby form a first cut groove as a first break start point on the back side 20b of the substrate 20 along each street 22. This first break start point forming step is performed by using a cutting apparatus 4 shown in FIG. 3. The cutting apparatus 4 shown in FIG. 3 includes a chuck table 41 for holding the optical device wafer 2 as a workpiece, cutting means 42 for cutting the workpiece held on the chuck table 41, and imaging means 43 for imaging the workpiece held on the chuck table 41. The chuck table 41 is so configured as to hold the workpiece under suction. The chuck table 41 is movable in a feeding direction shown by an arrow X in FIG. 3 by feeding means (not shown) and also movable in an indexing direction shown by an arrow Y in FIG. 3 by indexing means (not shown).

The cutting means 42 includes a spindle housing 421 extending in a substantially horizontal direction, a rotating spindle 422 rotatably supported to the spindle housing 421, and a cutting blade 423 mounted on the front end portion of the rotating spindle 422. The rotating spindle 422 is rotated in the direction shown by an arrow A in FIG. 3 by a servo motor (not shown) provided in the spindle housing 421. For example, the cutting blade 423 is an electroformed blade obtained by bonding diamond abrasive grains having a grain size of 3 μm with a nickel plating. The cutting blade 423 has a thickness of 20 μm. The imaging means 43 is mounted on the front end portion of the spindle housing 421. The imaging means 43 includes illuminating means for illuminating the workpiece, an optical system for capturing an area illuminated by the illuminating means, and an imaging device (CCD) for detecting an image corresponding to the area captured by the optical system. An image signal output from the imaging means 43 is transmitted to control means (not shown).

The first break start point forming step using the cutting apparatus 4 is performed in the following manner. As shown in FIG. 3, the optical device wafer 2 is placed on the chuck table 41 in the condition where the protective tape 3 attached to the front side 2a of the optical device wafer 2 comes into contact with the upper surface of the chuck table 41. By operating suction means (not shown), the optical device wafer 2 is held under suction on the chuck table 41 through the protective tape 3 (wafer holding step). Accordingly, the back side 20b of the sapphire substrate 20 of the optical device wafer 2 held on the chuck table 41 is oriented upward. The chuck table 41 thus holding the optical device wafer 2 under suction is moved to a position directly below the imaging means 43 by the feeding means.

When the chuck table 41 is positioned directly below the imaging means 43, an alignment operation is performed by the imaging means 43 and the control means to detect a cutting area of the optical device wafer 2. More specifically, the imaging means 43 and the control means perform the alignment between the cutting blade 423 and the streets 22 extending in a first direction on the front side 2a of the optical device wafer 2 (alignment step). Similarly, the imaging means 43 and the control means perform the alignment in a cutting area for the other streets 22 extending in a second direction perpendicular to the first direction on the front side 2a of the optical device wafer 2. Although the front side 2a of the optical device wafer 2, i.e., the front side of the light emitting layer 21 having the streets 22 in the optical device wafer 2 is oriented downward, the streets 22 can be imaged from the back side 20b of the sapphire substrate 20 because the sapphire substrate 20 is transparent.

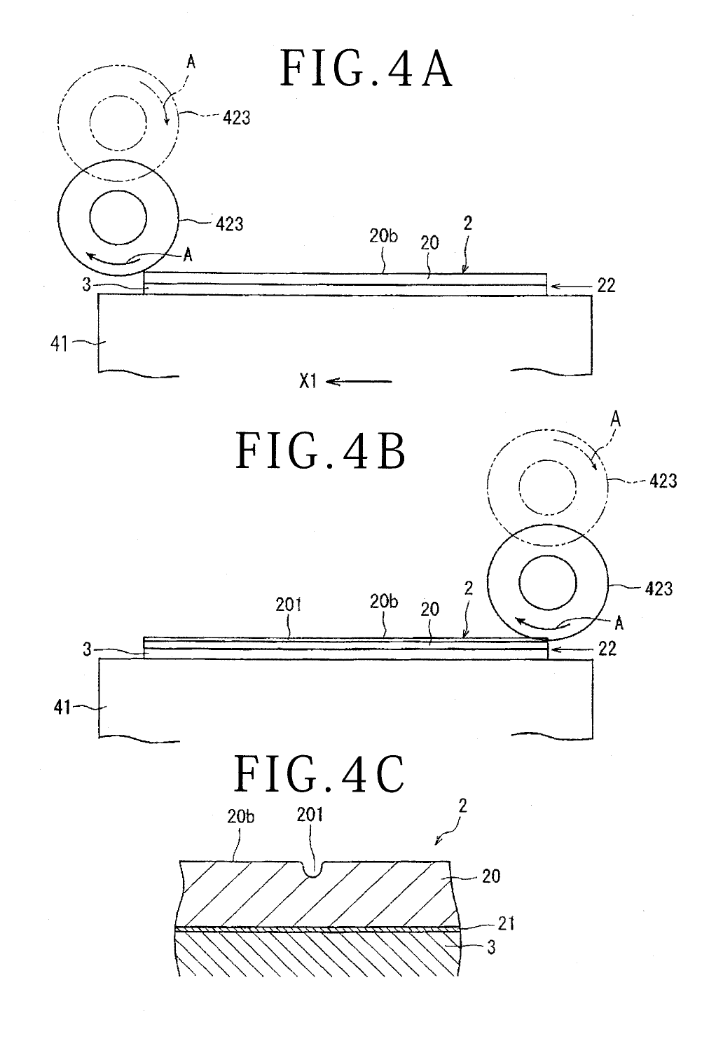

After performing the alignment operation for detecting the cutting area of the optical device wafer 2 held on the chuck table 41, the chuck table 41 holding the optical device wafer 2 is moved to a cutting start position in the cutting area below the cutting blade 423. At this cutting start position, one end (left end as viewed in FIG. 4A) of one of the streets 22 extending in the first direction is positioned on the right side of the cutting blade 423 by a predetermined amount (cutting start position setting step). When the optical device wafer 2 is set at this cutting start position as mentioned above, the cutting blade 423 is rotated in the direction shown by an arrow A in FIG. 4A and simultaneously moved down from a standby position shown by a two-dot chain line in FIG. 4A to a working position shown by a solid line in FIG. 4A, thus performing an infeed operation by a predetermined amount. This working position of the cutting blade 423 is set so that the outer circumference of the cutting blade 423 reaches a position at a predetermined depth (e.g., 20 μm) from the back side 20b (upper surface as viewed in FIG. 4A) of the sapphire substrate 20. If the depth of cut by the cutting blade 423 is greater than 20 μm, the load applied to the cutting blade 423 increases to cause chipping or cracking in the sapphire substrate 20. Therefore, the maximum value for the depth of cut by the cutting blade 423 is set to 20 μm.

After performing the infeed operation of the cutting blade 423, the chuck table 41 holding the optical device wafer 2 thereon is moved at a predetermined feed speed in the direction shown by an arrow X1 in FIG. 4A as rotating the cutting blade 423 at a predetermined rotational speed in the direction shown by an arrow A (first break start point forming step). As a result, a first cut groove 201 having a depth of 20 μm as a first break start point is formed on the back side 20b (upper surface) of the sapphire substrate 20 of the optical device wafer 2 so as to extend along the target street 22 extending in the first direction as shown in FIGS. 4B and 4C. In the first break start point forming step, the depth of cut by the cutting blade 423 is set to 20 μm, which is a relatively small value. Therefore, although the sapphire substrate 20 as a hard substrate is used, the first cut groove 201 as the first break start point can be formed relatively easily. When the other end (right end as viewed in FIG. 4B) of the target street 22 extending in the first direction reaches a position on the left side of the cutting blade 423 by a predetermined amount, the movement of the chuck table 41 is stopped. Thereafter, the cutting blade 423 is raised to a retracted position shown by a two-dot chain line in FIG. 4B.

The first break start point forming step is performed under the following processing conditions, for example.

Cutting blade: electroformed diamond blade having a thickness of 20 μm

Rotational speed of cutting blade: 20000 rpm

Depth of cut: 20 μm

Feed speed: 50 to 150 mm/sec

After performing the first break start point forming step along all of the streets 22 extending in the first direction on the optical device wafer 2, the chuck table 41 is rotated 90° to similarly perform the first break start point forming step along all of the streets 22 extending in the second direction perpendicular to the first direction.

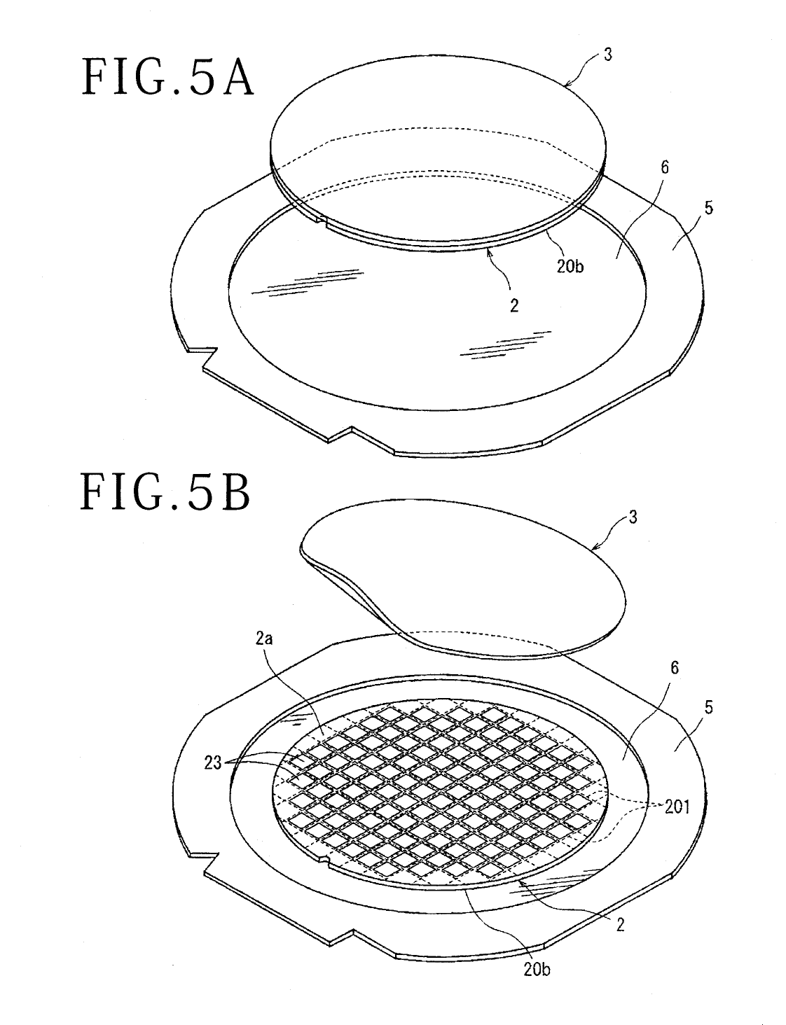

After performing the first break start point forming step along all of the streets 22 extending in the second direction, a wafer supporting step is performed in such a manner that the back side 20b of the sapphire substrate 20 of the optical device wafer 2 is attached to a dicing tape supported to an annular frame and that the protective member is removed from the front side 2a of the optical device wafer 2. More specifically, as shown in FIGS. 5A and 5B, a dicing tape 6 is supported at its outer circumferential portion of an annular frame 5 so as to close the inner opening of the annular frame 5. The back side 20b of the sapphire substrate 20 of the optical device wafer 2 is attached to the front side (adhesive surface) of the dicing tape 6. Thereafter, the protective tape 3 is peeled off from the front side 2a of the optical device wafer 2. Accordingly, the optical device wafer 2 is supported through the dicing tape 6 to the annular frame 5 in the condition where the front side 2a of the optical device wafer 2 is exposed.

After performing the wafer supporting step mentioned above, a second break start point forming step is performed in such a manner that the front side 2a of the optical device wafer 2 is cut along each street 22 by using a cutting blade mainly composed of diamond abrasive grains to thereby form a second cut groove as a second break start point on the front side 2a of the optical device wafer 2 along each street 22 so that the second cut groove has a depth reaching the front side 20a of the substrate 20. This second break start point forming step may be performed by using the cutting apparatus 4 shown in FIG. 3.

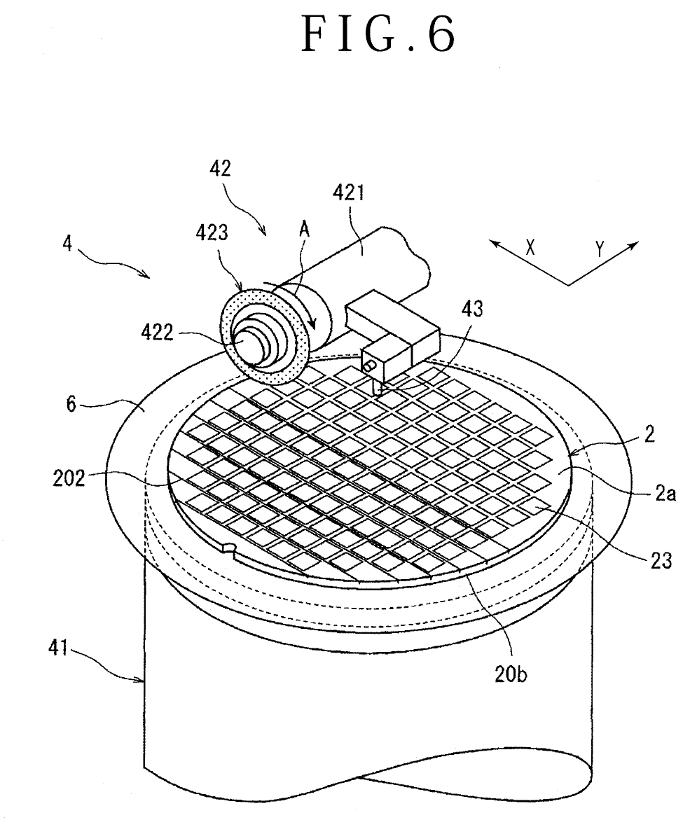

The second break start point forming step using the cutting apparatus 4 is performed in the following manner. As shown in FIG. 6, the optical device wafer 2 is placed on the chuck table 41 in the condition where the dicing tape 6 attached to the back side 20b of the sapphire substrate 20 of the optical device wafer 2 comes into contact with the upper surface of the chuck table 41. By operating the suction means, the optical device wafer 2 is held under suction on the chuck table 41 through the dicing tape 6 (wafer holding step). Accordingly, the front side 2a of the optical device wafer 2 held on the chuck table 41 is oriented upward. While the annular frame 5 supporting the dicing tape 6 is not shown in FIG. 6, the annular frame 5 is actually fixed by a clamp mechanism provided on the chuck table 41. The chuck table 41 thus holding the optical device wafer 2 under suction is moved to a position directly below the imaging means 43 by the feeding means.

When the chuck table 41 is positioned directly below the imaging means 43, an alignment operation is performed by the imaging means 43 and the control means to detect a cutting area of the optical device wafer 2. More specifically, the imaging means 43 and the control means perform the alignment between the cutting blade 423 and the streets 22 extending in the first direction on the front side 2a of the optical device wafer 2 (alignment step). Similarly, the imaging means 43 and the control means perform the alignment in a cutting area for the other streets 22 extending in the second direction perpendicular to the first direction on the front side 2a of the optical device wafer 2.

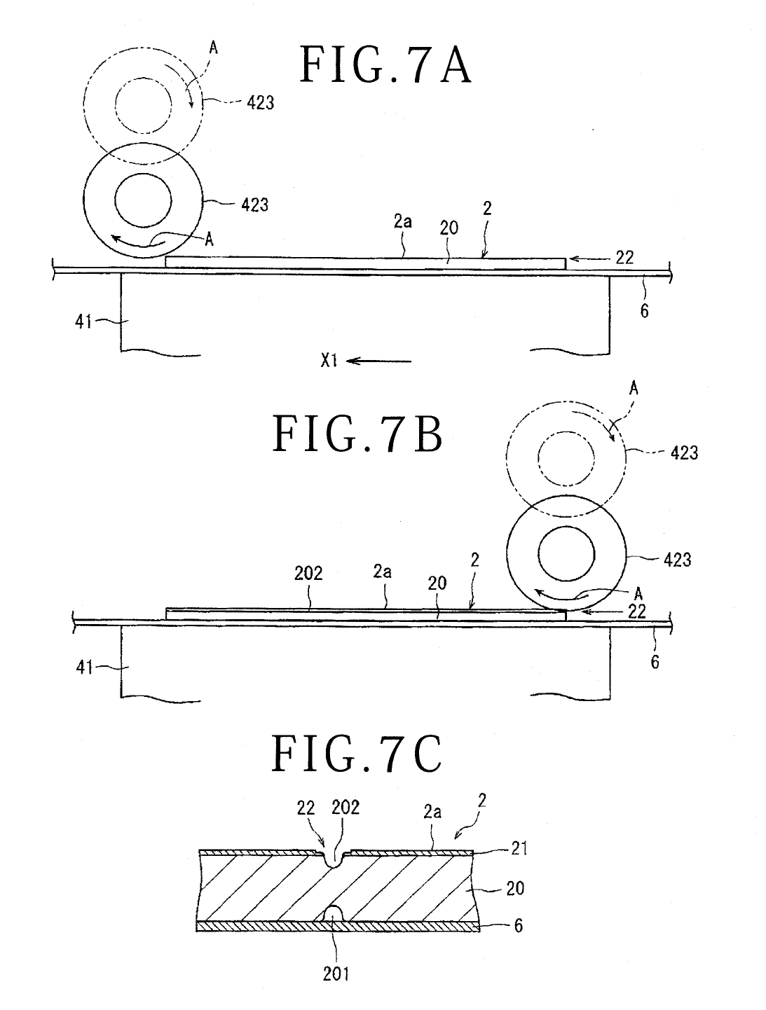

After performing the alignment operation for detecting the cutting area of the optical device wafer 2 held on the chuck table 41, the chuck table 41 holding the optical device wafer 2 is moved to a cutting start position in the cutting area below the cutting blade 423. At this cutting start position, one end (left end as viewed in FIG. 7A) of one of the streets 22 extending in the first direction is positioned on the right side of the cutting blade 423 by a predetermined amount (cutting start position setting step). When the optical device wafer 2 is set at this cutting start position as mentioned above, the cutting blade 423 is rotated in the direction shown by an arrow A in FIG. 7A and simultaneously moved down from a standby position shown by a two-dot chain line in FIG. 7A to a working position shown by a solid line in FIG. 7A, thus performing an infeed operation by a predetermined amount. This working position of the cutting blade 423 is set so that the outer circumference of the cutting blade 423 reaches a position at a predetermined depth (e.g., 20 μm) from the front side 2a (upper surface as viewed in FIG. 7A) of the optical device wafer 2.

After performing the infeed operation of the cutting blade 423, the chuck table 41 holding the optical device wafer 2 thereon is moved at a predetermined feed speed in the direction shown by an arrow X1 in FIG. 7A as rotating the cutting blade 423 at a predetermined rotational speed in the direction shown by the arrow A (second break start point forming step). The processing conditions in the second break start point forming step may be the same as those in the first break start point forming step mentioned above. As a result, a second cut groove 202 having a depth of 20 μm as a second break start point is formed on the front side 2a of the optical device wafer 2 so as to extend along the target street 22 extending in the first direction as shown in FIGS. 7B and 7C, wherein the depth of the second cut groove 202 reaches the front side 20a of the sapphire substrate 20. Also in the second break start point forming step similar to the first break start point forming step mentioned above, the depth of cut by the cutting blade 423 is set to 20 μm, which is a relatively small value. Therefore, although the sapphire substrate 20 as a hard substrate is used, the second cut groove 202 as the second break start point can be formed relatively easily. When the other end (right end as viewed in FIG. 7B) of the target street 22 extending in the first direction reaches a position on the left side of the cutting blade 423 by a predetermined amount, the movement of the chuck table 41 is stopped. Thereafter, the cutting blade 423 is raised to a retracted position shown by a two-dot chain line in FIG. 7B.

After performing the second break start point forming step along all of the streets 22 extending in the first direction on the optical device wafer 2, the chuck table 41 is rotated 90° to similarly perform the second break start point forming step along all of the streets 22 extending in the second direction perpendicular to the first direction.

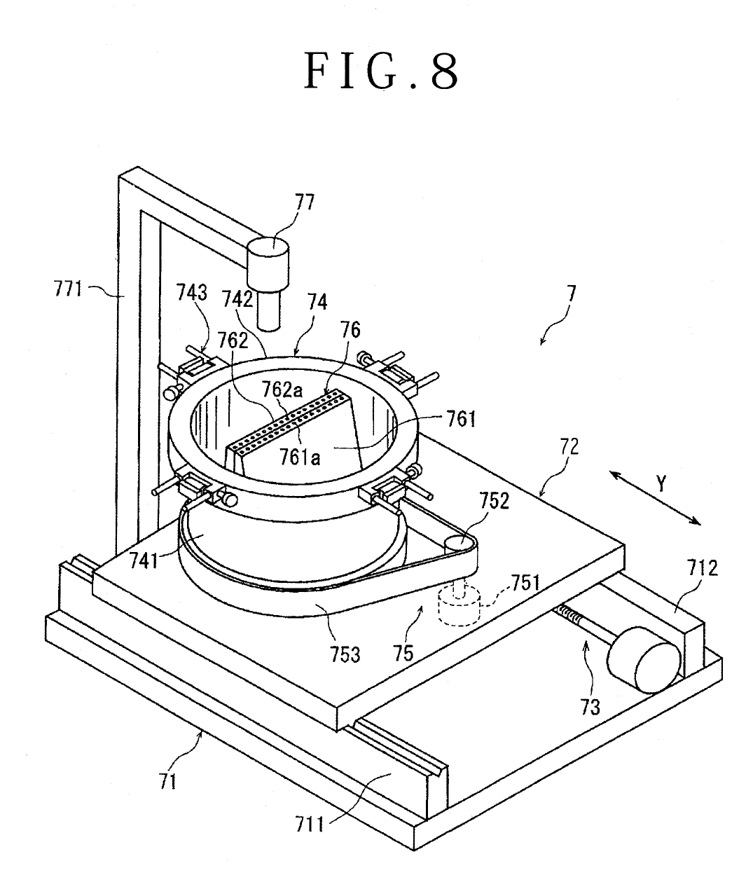

After performing the second break start point forming step along all of the streets 22 extending in the second direction, a wafer dividing step is performed in such a manner that an external force is applied to the optical device wafer 2 to thereby break the optical device wafer 2 along each street 22 where the first cut groove 201 and the second cut groove 202 are formed, thereby dividing the optical device wafer 2 into the individual optical devices 23. This wafer dividing step is performed by using a wafer dividing apparatus 7 shown in FIG. 8. The wafer dividing apparatus 7 shown in FIG. 8 includes a base 71 and a moving table 72 provided on the base 71 so as to be movable in the direction shown by an arrow Y in FIG. 8. The base 71 is a rectangular platelike member, and a pair of parallel guide rails 711 and 712 are provided on the upper surface of the base 71 near the opposite side portions thereof so as to extend in the direction of the arrow Y. The moving table 72 is movably mounted on the two guide rails 711 and 712. The moving table 72 is movable in the direction of the arrow Y by moving means 73. Frame holding means 74 for holding the annular frame 5 is provided on the moving table 72.

The frame holding means 74 includes a cylindrical body 741, an annular frame holding member 742 formed at the upper end of the cylindrical body 741, and a plurality of clamps 743 as fixing means provided on the outer circumference of the frame holding member 742. The annular frame 5 is placed on the frame holding member 742 and fixed by the clamps 743. The wafer dividing apparatus 7 further includes rotating means 75 for rotating the frame holding means 74. The rotating means 75 includes a pulse motor 751 provided on the moving table 72, a pulley 752 mounted on the rotating shaft of the pulse motor 751, and an endless belt 753 wrapped between the pulley 752 and the cylindrical body 741. By operating the pulse motor 751, the frame holding means 74 is rotated through the pulley 752 and the endless belt 753.

The wafer dividing apparatus 7 shown in FIG. 8 further includes tension applying means 76 for applying a tensile force to the optical device wafer 2 in a direction perpendicular to the streets 22 extending in a predetermined direction in the condition where the optical device wafer 2 is supported through the dicing tape 6 to the annular frame 5 held on the annular frame holding member 742. The tension applying means 76 is provided inside the annular frame holding member 742. The tension applying means 76 includes a first suction holding member 761 and a second suction holding member 762, wherein each of the first and second suction holding members 761 and 762 has a rectangular holding surface elongated in a direction perpendicular to the direction of the arrow Y in FIG. 8. The first suction holding member 761 is formed with a plurality of suction holes 761a, and the second suction holding member 762 is formed with a plurality of suction holes 762a. These plural suction holes 761a and 762a are connected to suction means (not shown). The first and second suction holding members 761 and 762 are individually movable in the direction of the arrow Y by moving means (not shown). The tension applying means 76 and the frame holding means 74 are relatively movable in the direction of the arrow Y.

The wafer dividing apparatus 7 shown in FIG. 8 further includes detecting means 77 for detecting the streets 22 of the optical device wafer 2 supported through the dicing tape 6 to the annular frame 5 held on the annular frame holding member 742. The detecting means 77 is mounted on an L-shaped support member 771 standing from the base 71. The detecting means 77 is constituted of an optical system, an imaging device (CCD), etc., and it is located above the tension applying means 76. The detecting means 77 functions to image the streets 22 of the optical device wafer 2 supported through the dicing tape 6 to the annular frame 5 held on the annular frame holding member 742 and to transmit an image signal as an electrical signal to control means (not shown).

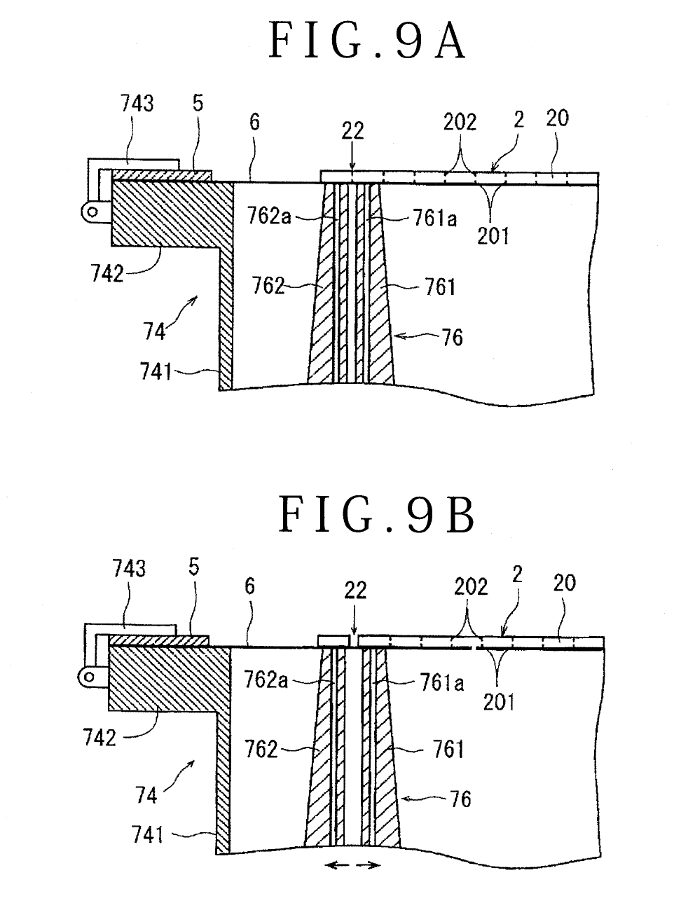

The wafer dividing step using the wafer dividing apparatus 7 mentioned above will now be described with reference to FIGS. 9A and 9B. The annular frame 5 supporting the optical device wafer 2 through the dicing tape 6 is placed on the frame holding member 742 and is next fixed to the frame holding member 742 by the clamps 743 as shown in FIG. 9A. Thereafter, the moving means 73 is operated to move the moving table 72 in the direction of the arrow Y shown in FIG. 8 so that a predetermined one of the streets 22 extending in the first direction perpendicular to the direction of the arrow Y (e.g., the leftmost street 22 as viewed in FIG. 9A) is positioned between the holding surface of the first suction holding member 761 of the tension applying means 76 and the holding surface of the second suction holding member 762 of the tension holding means 76 as shown in FIG. 9A. At this time, the predetermined street 22 is imaged by the detecting means 77 to position the holding surfaces of the first and second suction holding members 761 and 762 with respect to the predetermined street 22. Thereafter, the suction means (not shown) is operated to produce a vacuum in the suction holes 761a and 762a, thereby holding the optical device wafer 2 through the dicing tape 6 on the holding surfaces of the first and second suction holding members 761 and 762 (holding step).

After performing this holding step, the moving means (not shown) for composing the tension applying means 76 is operated to move the first suction holding member 761 and the second suction holding member 762 in the opposite directions (the direction of the arrow Y shown in FIG. 8) as shown in FIG. 9B. As a result, the predetermined street 22 positioned between the holding surface of the first suction holding member 761 and the holding surface of the second suction holding member 762 receives a tensile force in the direction of the arrow Y perpendicular to the predetermined street 22, so that the optical device wafer 2 is broken along this predetermined street 22 where the first cut groove 201 as the first break start point is formed on the back side 20b of the sapphire substrate 20 and the second cut groove 202 as the second break start point is formed on the front side 2a of the optical device wafer 2 so as to reach the front side 20a of the sapphire substrate 20 (breaking step). In this breaking step, the dicing tape 6 is slightly stretched. The first and second cut grooves 201 and 202 are formed along each street 22 and the strength of the optical device wafer 2 is reduced along each street 22. Accordingly, when the first and second suction holding members 761 and 762 holding the optical device wafer 2 are moved in the opposite directions by a small amount of about 0.5 mm, for example, the optical device wafer 2 can be easily broken along the predetermined street 22 where the first and second cut grooves 201 and 202 are formed on the sapphire substrate 20 as a break start point.

After performing the breaking step of breaking the optical device wafer 2 along the predetermined street 22 extending in the first direction mentioned above, the suction holding of the optical device wafer 2 by the first and second suction holding members 761 and 762 is canceled. Thereafter, the moving means 73 is operated again to move the moving table 72 in the direction of the arrow Y shown in FIG. 8 by an amount corresponding to the pitch of the streets 22 so that the next street 22 adjacent to the predetermined street 22 mentioned above is positioned between the holding surface of the first suction holding member 761 and the holding surface of the second suction holding member 762 of the tension applying means 76. Thereafter, the holding step and the breaking step are performed similarly.

After performing the holding step and the breaking step for all of the streets 22 extending in the first direction, the rotating means 75 is operated to 90° rotate the frame holding means 74. As a result, the optical device wafer 2 held to the frame holding member 742 of the frame holding means 74 is also rotated 90°, so that the other streets 22 extending in the second direction perpendicular to the streets 22 extending in the first direction and performed the breaking step becomes parallel to the longitudinal direction of the holding surfaces of the first and second suction holding members 761 and 762. Thereafter, the holding step and the breaking step are performed similarly for all of the other streets 22 extending in the second direction perpendicular to the streets 22 extending in the first direction and performed the breaking step, thereby dividing the optical device wafer 2 into the individual optical devices 23 (wafer dividing step).

In this preferred embodiment, the first cut groove 201 as the first break start point is formed along each street 22 on the back side 20b of the sapphire substrate 20 of the optical device wafer 2 by using a cutting blade, and the second cut groove 202 as the second break start point is formed along each street 22 on the front side 2a of the optical device wafer 2 by using a cutting blade so as to reach the front side 20a of the sapphire substrate 20. Thereafter, the optical device wafer 2 is broken along each street 22 where the first and second cut grooves 201 and 201 are formed as a break start point, thereby dividing the optical device wafer 2 into the individual optical devices 23. Accordingly, cracks contributing to the division of the optical device wafer 2 grow from the first and second cut grooves 201 and 202 as the break start point formed on the back side 20b and the front side 20a of the sapphire substrate 20, respectively, thereby attaining effective division of the optical device wafer 2. Further, a modified substance absorbing light to cause a reduction in luminance is not produced, so that the luminance of each optical device 23 is not reduced.

Further, the first cut grooves 201 as the first break start point and the second cut grooves 202 as the second break start point are formed by a cutting blade mainly composed of diamond abrasive grains. Accordingly, the inner surfaces of the first and second cut grooves 201 and 202 are formed as rough surfaces, so that light can be effectively emitted from each optical device 23, thereby improving the luminance.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An optical device wafer processing method for dividing an optical device wafer into individual optical devices along a plurality of crossing streets formed on the front side of said optical device wafer, said optical device wafer being composed of a substrate and an optical device layer formed on the front side of said substrate, said individual optical devices being respectively formed in a plurality of regions partitioned by said streets, said optical device wafer processing method comprising:
a first break start point forming step of cutting the back side of said substrate along each street by using a cutting blade mainly composed of diamond abrasive grains to thereby form a first cut groove as a first break start point on the back side of said substrate along each street;
a second break start point forming step of cutting the front side of said optical device wafer along each street by using a cutting blade mainly composed of diamond abrasive grains after performing said first break start point forming step to thereby form a second cut groove as a second break start point on the front side of said optical device wafer along each street so that said second cut groove has a depth reaching the front side of said substrate; and
a wafer dividing step of applying an external force to said optical device wafer after performing said second break start point forming step to thereby break said optical device wafer along each street where said first cut groove and said second cut groove are formed, thereby dividing said optical device wafer into said individual optical devices.
